(19) United States
(12) Patent Application Publication
(10) Pub. No.: US 2008/0042862 A1
(43) Pub. Date: Feb. 21, 2008

(54) ALARM DEVICE FOR INDICATING EXCESSIVE STATIC ELECTRICITY

(75) Inventors: XIAO-ZHU CHEN, Shenzhen (CN); KE SUN, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/565,648

(22) Filed: Dec. 1, 2006

(30) Foreign Application Priority Data
Aug. 11, 2006 (CN) 200610062081.3

(51) Int. Cl. G08B 21/00; G01R 29/12; H05F 3/02

(52) U.S. Cl. 340/649; 324/457; 361/212

(57) ABSTRACT

An alarm device is provided for monitoring a level of static electricity on an object. The alarm device includes a detection unit and an alarm unit. The detection unit detects the level of static electricity on the object and generates a detection signal accordingly. The alarm unit, coupled between a power source and the detection unit, generates a warning signal in response to the detection signal when the detected level of static electricity exceeds a predetermined level.

### BACKGROUND OF THE INVENTION

1. Field of the Invention

The present invention relates to an alarm device, and particularly to an alarm device for indicating excessive static electricity occurring on an object.

2. Description of Related Art

Static electricity is commonly accumulated on human bodies or various objects. When a human body or an object carrying excessive electrostatic charge approaches or touches an electronic apparatus, an electrostatic discharge (ESD) may occur on the surface of the electronic apparatus, degrading the sensitivity of the electronic apparatus or even damaging electronic components thereof. Thus, there exists a need for an alarm device for warning users of excessive electrostatic charge of electronic apparatuses.

### SUMMARY OF THE INVENTION

An alarm device for monitoring a level of static electricity on an object is provided. In a preferred embodiment, the alarm device comprises a detection unit and an alarm unit. The detection unit detects the level of static electricity on the object and generates a detection signal accordingly. The alarm unit, coupled between a power source and detection unit, generates a warning signal in response to the detection signal when the detected level of static electricity exceeds a predetermined level.

Another alarm device attached to a computer case for indicating excessive static electricity occurring thereon is further provided. The alarm device comprises an amplifier, a transistor, and an alarm. The amplifier comprises a positive terminal, electrically connected to the computer case, receiving an input signal having a level corresponding to that of static electricity on the computer case, a negative terminal coupled to ground, and an output terminal generating an amplified signal in response to the received input signal. The transistor comprises an emitter coupled to ground, and a base coupled to the output terminal of the amplifier, receiving the amplified signal. The alarm, coupled between a collector of the transistor and a power source, generates a warning signal when the detected level of static electricity exceeds a predetermined level.

Other advantages and novel features will become more apparent from the following detailed description when taken in conjunction with the accompanying drawings, in which:

### BRIEF DESCRIPTION OF THE DRAWINGS

FIG. 1 is an isometric, schematic view of an alarm device attached to a computer side panel in accordance with a preferred embodiment of the invention;

FIG. 2 is an enlarged view of the alarm device of FIG. 1; and

FIG. 3 is a circuit diagram of the alarm device of FIG. 1.

### DETAILED DESCRIPTION OF THE INVENTION

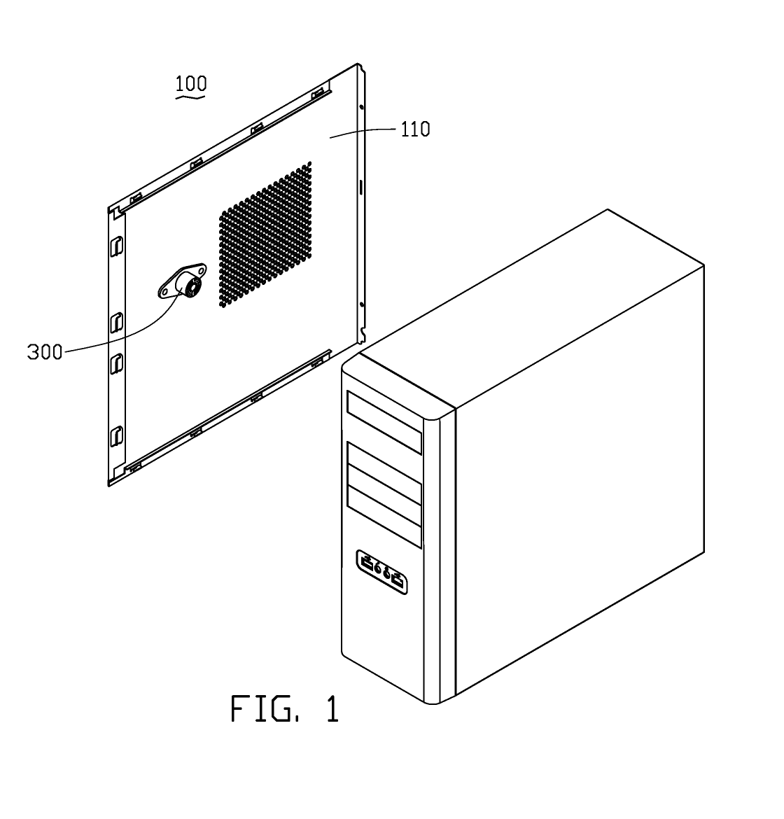

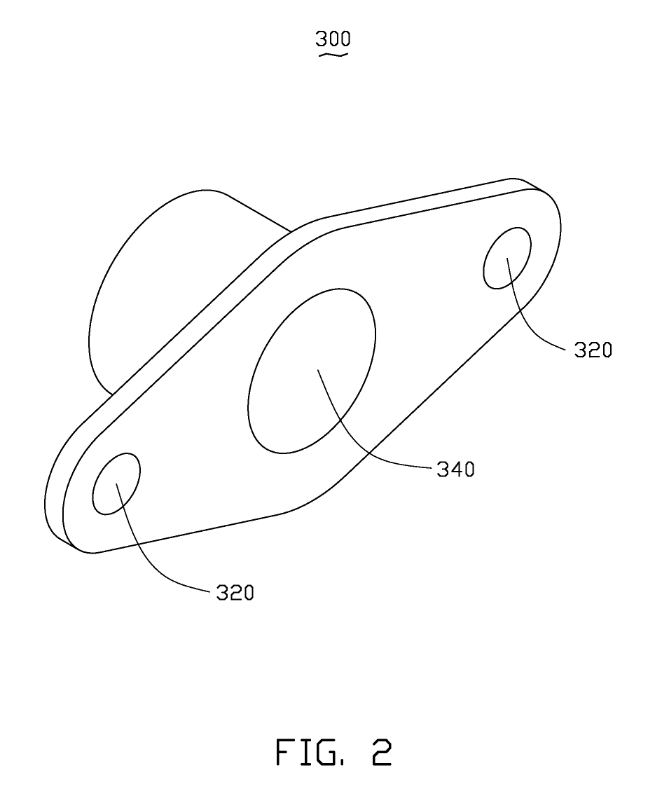

FIG. 1 shows an alarm device 200 disposed in a housing 300 for detecting a level of static electricity occurring on a computer 100 according to an embodiment of the invention. The alarm device 200 is preferably attached to a side panel 110 of the computer 100 to warn users of the computer 100 of excessive electrostatic electricity thereon. Referring to FIG. 2, the housing 300 comprises a terminal 340 electrically connected to the side panel 110 and a pair of pads 320 capable of being attached to an inner surface of the side panel 110 of the computer 100.

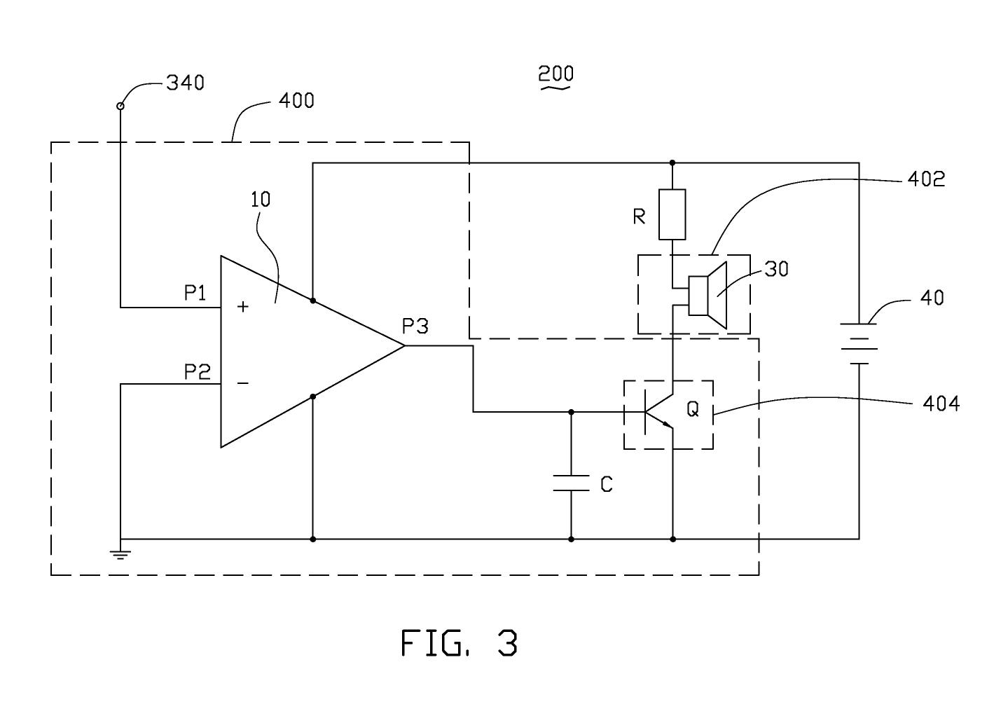

FIG. 3 shows an exemplary embodiment of the alarm device 200 comprising a detection unit 400, an alarm unit 402, a resistor R, and a power source 40, preferably a battery. The detection unit 400 detects the level of static electricity on the side panel 110 of the computer 100 and generates a detection signal accordingly. The alarm unit 402 comprises an alarm 30 coupled to a positive terminal of the power source 40 via the resistor R, and the detection unit 400. The alarm 30 generates a warning signal in response to the detection signal from the detection unit 400 when the detected level of static electricity exceeds a predetermined level.

The detection unit 400 comprises an amplifier 10, a switch element 404, and a capacitor C. The amplifier 10, powered by the power source 40, comprises a positive input terminal P1 connected to the terminal 340 receiving an input signal corresponding to the level of static electricity on the side panel 110, a negative input terminal P2 connected to a negative terminal of the power source 40 and ground, and an output terminal P3 generating an amplified signal in response to the received input signal. The switch element 404, coupled to the output terminal P3, alarm unit 402, and ground, is turned on in response to the amplified signal from the amplifier 10. The switch element 404 comprises a transistor Q comprising an emitter coupled to ground, a base coupled to the output terminal P3 of the amplifier 10, receiving the amplified signal, and a collector coupled to the alarm unit 402. The capacitor C is coupled between the output terminal P3 and ground. The operation of the alarm device 200 is described as follows.

When a human body or an object carrying electrostatic charge approaches or touches the computer 100, the positive input terminal P1 of the amplifier 10 receives the input signal having a level corresponding to that of static electricity on the side panel 110 from the terminal 340 and generates the amplified signal at the output terminal P3 of the amplifier 10. If the level of static electricity on the side panel 110 is so low that it is harmless for the computer 100 and beyond the sensing threshold of the amplifier 10, the amplifier 10 generates the amplified signal at a low state, indicating the level of static electricity on the side panel 110 is within a safety range. The transistor Q is not turned on and the alarm 30 cannot generate a warning signal. Conversely, if the level of static electricity on the side panel 110 exceeds the sensing threshold of the amplifier 10, the amplifier 10 generates the amplified signal at a high state. Thus, the transistor Q is turned on, charging the capacitor C and allowing the alarm 30 to emit a sound, warning users about the existence of excessive static electricity on the side panel 110. If the human body or object moves away from the computer 100, the capacitor C is discharged, allowing the transistor Q to remain on allowing the alarm 30 keep sounding for a time.

As shown, an operational amplifier and a buzzer are utilized as the exemplary amplifier 10 and alarm 30 respectively. Other components capable of amplifying an input signal can be utilized as the amplifier 10 in accordance with the principles of the invention. Similarly, other components capable of generating signals of warning users, such as a light-emitting diode (LED), can also be utilized herein with the principles of the invention. Moreover, it is noted that the alarm 30 is not limited to be attached to an inside of the side panel 110 as shown in the FIG. 1, conversely, it can be attached to an outside of the side panel 110. When a buzzer is utilized as the alarm 30 and attached to the inside of the side panel 110, it is preferred to attach the buzzer to a location adjacent to a vent area of the side panel 110, which defines a plurality of vent holes. In this way, users may hear a warning sound emitted by the buzzer clearly.

Thus, if excessive static electricity on the computer 100 occurs, it can be identified with exemplary embodiments, avoiding damage to individuals or electronic components of the computer 100.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. An alarm device monitoring a level of static electricity on an object, comprising:
a detection unit detecting the level of static electricity on the object and generating a detection signal accordingly; and
an alarm unit coupled between a power source and the detection unit, generating a warning signal in response to the detection signal when the detected level of static electricity exceeds a predetermined level.

2. The alarm device as claimed in claim 1, wherein the detection unit comprises an amplifier coupled to the power source, comprising a first terminal receiving an input signal having a level corresponding to that of static electricity on the object, a second terminal coupled to ground, and an output terminal generating an amplified signal in response to the received input signal.

3. The alarm device as claimed in claim 2, wherein the first terminal is electrically connected to the object.

4. The alarm device as claimed in claim 2, wherein the amplifier is an operational amplifier.

5. The alarm device as claimed in claim 2, wherein the detection unit further comprises a switch element coupled to the output terminal, the alarm unit, and ground, being turned on in response to the amplified signal.

6. The alarm device as claimed in claim 5, wherein the switch element comprises a transistor comprising an emitter coupled to ground, a collector coupled to the alarm unit, and a base coupled to the output terminal of the amplifier, receiving the amplified signal.

7. The alarm device as claimed in claim 2, wherein the detection unit further comprises a capacitor coupled between the output terminal of the amplifier and ground.

8. The alarm device as claimed in claim 1, further comprising a resistor coupled between the power source and the alarm unit.

9. The alarm device as claimed in claim 1, wherein the alarm unit is a buzzer.

10. The alarm device as claimed in claim 1, wherein the alarm device is attached to the object.

11. The alarm device as claimed in claim 10, wherein the alarm device is disposed in a housing comprising a pad for being attached to the object.

12. An alarm device attached to a computer case for indicating excessive static electricity occurring thereon, comprising:
an amplifier, comprising a positive input terminal, electrically connected to the computer case, receiving an input signal having a level corresponding to that of static electricity on the computer case, a negative input terminal coupled to ground, and an output terminal generating an amplified signal in response to the received input signal;
a transistor comprising an emitter coupled to ground, and a base coupled to the output terminal of the amplifier, receiving the amplified signal; and
an alarm coupled between a collector of the transistor and a power source, generating a warning signal when the detected level of static electricity exceeds a predetermined level.

13. The alarm device as claimed in claim 12, further comprising a capacitor coupled between the output terminal of the amplifier and ground.

14. The alarm device as claimed in claim 12, wherein the alarm is a buzzer.

15. The alarm device as claimed in claim 12, wherein the amplifier is an operational amplifier.

16. The alarm device as claimed in claim 12, wherein the alarm device is disposed in a housing comprising a pad for being attached to the computer case.

17. The alarm device as claimed in claim 16, wherein the computer case comprises a side panel having a vent area defining a plurality of vent holes and the housing is attached to an inside of the side panel of the computer case adjacent to the vent area.
